(19) United States
(12) Patent Application Publication
(10) Pub. No.: US 2003/0060062 A1
(43) Pub. Date: Mar. 27, 2003

(54) Flexible Printed Circuit Board Having Conductor Lands Formed Thereon

(75) Inventors: Sumito Honda, Tokyo (JP); Takashi Suzuki, Tokyo (JP)

Correspondence Address: FRISHAUF, HOLTZ, GOODMAN & CHICK, PC, 767 THIRD AVENUE, 25TH FLOOR, NEW YORK, NY, 10017-2023, US

(73) Assignee: Olympus Optical Co., Ltd., Tokyo (JP)

(21) Appl. No.: 10/247,393

(22) Filed: Sep. 19, 2002

(30) Foreign Application Priority Data
Sep. 27, 2001 (JP) 2001-297702

(51) Int. Cl. H05K 1/00

(52) U.S. Cl. 439/67

(57) ABSTRACT

On the surface of a flexible printed circuit board according to the present invention, at least one conductive land formed of a conductive pattern for mounting a component thereon which is to be mounted on the flexible printed circuit board, at least one first conductor line lead formed of another conductive pattern which extends from the conductor land and which forms an electrical connection of the conductor land, at least one second conductor line lead formed of another conductive pattern which extends in a direction orthogonal to the first conductor line lead and which extends from the conductor land for forming an electrical connection of the conductor land, and at least one semi-circular conductor line for electrically connecting the end of the first conductor line lead and the end of the second conductor line lead are formed.

This application claims benefit of Japanese Application No. 2001-297702 filed in Japan on Sep. 27, 2001, the contents of which are incorporated by this reference.

### BACKGROUND OF THE INVENTION

1. Field of the Invention

The present invention relates to flexible printed circuit boards, and more particularly, the present invention relates to a flexible printed circuit board used for mounting a surface mounted component thereon and for maintaining an electrically connected state of the surface mounted component even when a part of line lead conductive patterns which are led out from conductor lands and which are used for an electrical connection of the surface mounted component is broken.

2. Description of the Related Art

A demand for reducing the sizes of electronic apparatuses requires reducing development for reducing the sizes of printed circuit boards and the sizes of electrical components which are mounted on the flexible printed circuit boards. Also, in order to effectively dispose the printed circuit boards in the electronic apparatuses, flexible printed circuit boards have been widely used.

Widely used surface mounted components which are mounted on the flexible printed circuit boards (hereinafter, referred to FPC boards) have external dimensions of 1.6×0.8 mm (hereinafter, called as 1608 size components) or larger. Hereinafter these components will be collectively called as standard size components.

Meantime, as a result of development for further reducing the sizes of the surface mounted components, newly developed reduced-size components having external dimensions of 1.0×0.5 mm (hereinafter, called as 1005 size components) and even 0.6×0.3 mm (hereinafter, called as 0603 size components) are in practical use. Hereinafter these components will be collectively called as small size components.

Referring to FIGS. 6 to 8, known example FPC boards having such standard and small size components mounted thereon will be described.

FIG. 6 is a plan view illustrating a known FPC board having a standard size component mounted thereon, FIG. 7 is a plan view illustrating another known FPC board having a small size component mounted thereon, and FIG. 8 is a sectional view illustrating a problem of the known FPC board having the small size component mounted thereon.

Referring to FIG. 6, the known FPC board having a standard size component mounted thereon will be described. In order to mount a standard size component 20 on an FPC board 21, a pair of conductor lands 22, which are formed of conductive patterns having large areas and on which end electrodes of the standard size component 20 are placed for being mounted by soldering, and a pair of conductor lines 23, which are connected to the corresponding conductor lands 22 and which are formed of conductive patterns, are formed on a substrate of the FPC board 21. In addition, a cover layer 24 having a cover layer opening 24a is formed on the substrate of the FPC board. The cover layer 24 allows the standard size component 20 and parts of the conductor lands 22 to be exposed to the outside from the cover layer opening 24a and is bonded to the FPC board 21 so as to press the remaining parts of the conductor lands 22 on the substrate.

That is, the end electrodes of the standard size component 20 are placed on the conductor lands 22 and are soldered to them so as to electrically connect the standard size component 20 to the conductor lands 22. Then, the cover layer 24 is bonded to the FPC board so as to protect parts of the conductor lands 22 and the conductor lines 23. This arrangement prevents the conductor lands 22 and the conductor lines 23 from being broken or being stripped off from the substrate of the FPC board 21 when the FPC board 21 is bent.

As described above, when the standard size component 20 is mounted on the FPC board 21, at least one side among the four sides of each conductor land 22 for electrically connecting the standard size component 20 thereto is widely covered by the cover layer 24. Therefore, even when a bending moment caused by bending the FPC board 21 is applied on the conductor lands 22 and the conductor lines 23, the conductor lands 22 and the conductor lines 23 are unlikely to be broken or stripped off from the substrate.

Meanwhile, the conductor lands 22 for mounting a small size component such as a 1005 size component or a 0603 size component on an FPC board have small areas so as to form similar profiles to those of the end electrodes of the small size component. With this structure, when the cover layer 24 is bonded to the FPC board so as to cover at least one whole side of each conductor land 22 in the same fashion as to the standard size component 20 illustrated in FIG. 6, the cover layer 24 tends to be bonded in a displaced manner with respect to the small conductor lands 22. This bonding displacement of the cover layer 24 causes the shapes of the pair of conductor lands 22 to be asymmetrical, thereby giving rise to a problem in that, when the small size component is mounted on the FPC board, the small size component is detached from the FPC board, is not connected to the conductor lands 22, or the like.

In order to prevent such problems including the detachment and the non-connection of the small size component, as shown in FIG. 7, an FPC board 10 used for mounting a small size component 11 thereon has end electrodes of the small size component 11 mounted thereon by soldering. In addition, the FPC board 10 has a pair of conductor lands 12, each having a similar profile to that of the end electrode of the small size component 11, a pair of conductor line leads 13a led out from the respective conductor lands 12, and a pair of conductor lines 13 for connecting the small size component 11 to other components via the corresponding conductor line leads 13a formed thereon.

A cover layer 14 is bonded to the conductor lands 12 and has a cover layer opening 14a, which is formed larger than the pair of conductor lands 12 so as to expose all sides of the conductor lands 12 to the outside. The cover layer 14 having such a shape reduces the affect of the bonding displacement between the small size component 11 and the conductor lands 12.

Since the FPC board 10 has a problem when it has a structure in which each conductor land 12 has a similar shape to that of the end electrode of the small size component 11 and the cover layer opening 14a is formed so as to expose the four sides of each conductor land 12 to the outside, as shown in FIG. 7, the problem will be described with reference to FIG. 8 illustrating a double-sided FPC board.

On the front surface of a substrate 16 of the double-sided FPC board, a pair of front surface conductive patterns 15 including the respective conductor lines 13, the conductor lands 12 which are connected to the corresponding front surface conductive patterns 15 and having the respective end electrodes of the small size component 11 mounted thereon, and the conductor line leads 13a which are led out from the respective conductor lines 13 and which are connected to the corresponding conductor lands 12 are formed. The front surface conductive patterns 15 have the cover layer 14 bonded on the surface thereof. The cover layer opening 14a is formed in a place where the conductor line leads 13a lie. The end electrodes of the small size component 11 are mounted on the corresponding conductor lands 12 and electrically connected to them with a pair of solders 26.

On the rear surface of the double-sided FPC board, a rear surface conductive pattern 17 formed on the substrate 16 and a rear surface cover layer 18 bonded to the substrate 16 so as to cover the rear surface conductive pattern 17 are formed.

That is, as described above, the cover layer opening 14a of the cover layer 14 is larger than the pair of conductor lands 12 and is bonded to the substrate 16 in a manner such that the small size component 11, the conductor lands 12 and the conductor line leads 13a serving as parts of the conductor lines 13 are exposed to the outside from the cover layer opening 14a.

As shown in FIGS. 7 and 8, in the FPC board 10 used for mounting the small size component 11 thereon, the conductor lands 12 and the corresponding conductor lines 13 or the corresponding front surface conductive patterns 15 are connected with the corresponding conductor line leads 13a formed of fine conductor patterns.

With this configuration, when the FPC board 10 is bent in the vicinity of one of the conductor line leads 13a as shown in FIG. 8, a largest bending moment 29 is applied to the conductor line lead 13a lying in the outermost layer with respect to the center of the bending moment 29. Since the conductor line lead 13a is not protected by the cover layer 14, this bending moment 29 causes a breakage 27 of the conductor line lead 13a. Although a reinforcing plate serving as a prevention against a bending moment is bonded to the rear surface of the FPC board 10 in order to prevent the breakage of the conductor line leads 13a, this preventive measure causes an increased cost of the FPC board 10, and also requires an additional volume of the FPC board 10 for attaching the reinforcing plate thereon, thereby causing a problem in that a reduced size of an FPC board or an electronic apparatus is not achieved.

### SUMMARY OF THE INVENTION

Accordingly, it is an object of the present invention to provide a flexible printed circuit board, having conductor lands formed thereon, used for mounting a small size component such as a 1005 size component or a smaller one thereon, which maintains electrical connections between the conductor lands and corresponding conductor lines even when a part of conductor line leads connecting the conductor lands and the respective conductor lines is broken or in which the conductor line leads are unlikely to be broken.

A flexible printed circuit board according to the present invention comprises: a conductor land formed of a conductive pattern for mounting a component thereon which is to be mounted on the flexible printed circuit board; a first conductor line lead formed of another conductive pattern which extends from the conductor land and which forms an electrical connection of the conductor land; and at least one second conductor line lead formed of another conductive pattern for electrically connecting the conductor land and the first conductor line lead, wherein the conductor land, a part of the first conductor line lead, and the second conductor line lead form a conductive loop on the flexible printed circuit board.

This objects and advantages of the present invention will become further apparent from the following detailed explanation.

### BRIEF DESCRIPTION OF THE DRAWINGS

FIG. 1 is an FPC board according to a first embodiment of the present invention;

FIG. 2 is an FPC board according to a second embodiment of the present invention;

FIG. 3 is an FPC board according to a third embodiment of the present invention;

FIG. 4 is an FPC board according to a fourth embodiment of the present invention;

FIG. 5 illustrates a state in which the FPC board according to the fourth embodiment is used;

FIG. 6 illustrates a known FPC board having a standard size component mounted thereon;

FIG. 7 illustrates another known FPC board having a small size component mounted thereon; and

FIG. 8 is a sectional view illustrating a problem of the known FPC board having a small size component mounted thereon.

### DESCRIPTION OF THE PREFERRED EMBODIMENTS

Embodiments of the present invention will be described with reference to the accompanying drawings.

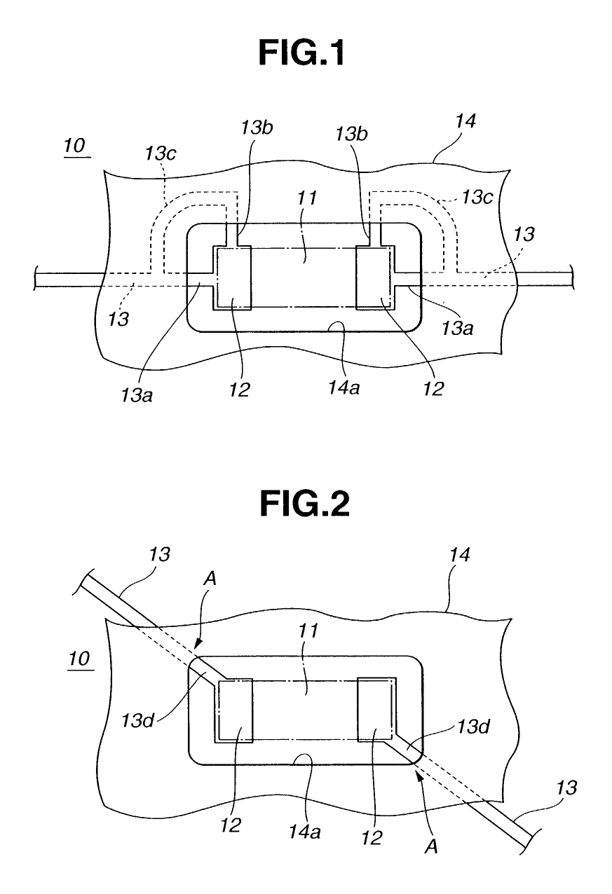

Referring to FIG. 1, a flexible printed circuit board (hereinafter, referred to an FPC board) according to a first embodiment of the present invention will be described.

End electrodes (not shown) of a small size component 11 which is to be mounted are placed and conductive patterns are disposed, both on the surface of an FPC board 10, wherein the conductive patterns form a pair of conductor lands 12 electrically connected to the end electrodes by soldering or the like, a pair of first conductor line leads 13a and a pair of second conductor line leads 13b, both extending from the conductor lands 12, a pair of semi-circular conductor lines 13c, each having a semi-circular shape so as to connect the ends of the corresponding first and second conductor line leads 13a and 13b, and a pair of conductor lines 13 extending from the junctions between the ends of the first conductor line leads 13a and the corresponding semi-circular conductor lines 13c.

The first conductor line leads 13a are formed in the longitudinal direction of the small size component 11 which is to be mounted between the pair of conductor lands 12. The second conductor line leads 13b are formed in a direction orthogonal to the first conductor line leads 13a.

In other words, the pair of conductor lands 12 having the small size component 11 connected thereto, the first conductor line leads 13a functioning as primary leads and extending from the conductor lands 12, and a pair of conductor loops, each configured by the conductor land 12, a part of the first conductor line lead 13a, the second conductor line lead 13b, and the semi-circular conductor line 13c, are formed on the surface of the FPC board 10.

The conductor lines 13 are connected to other components (not shown) at the ends thereof.

A cover layer opening 14a of a cover layer 14 has a similar profile to the upper surface profile of the small size component 11 and has dimensions so that the small size component 11, the conductor lands 12, and parts of the first and second conductor line leads 13a and 13b extending from the conductor lands 12 are exposed to the outside from the cover layer opening 14a.

In other words, the cover layer 14 covers parts of the first conductor line leads 13a functioning as primary leads and extending from the pair of conductor lands 12 in two directions, parts of the second conductor line leads 13b functioning as secondary leads, the semi-circular conductor lines 13c, and the conductor lines 13.

Even when a bending moment is applied on the FPC board 10 by bending it in any direction, having the first and second conductor line leads 13a and 13b, each extending from the pair of conductor lands 12 in two directions, the small size component 11 can maintain its connection to the conductor lines 13. For example, when the FPC board 10 is bent in a direction in which the first conductor line leads 13a are likely to be broken, since the second conductor line leads 13b are led out from the conductor lands 12 in a direction in which the second conductor line leads 13b are unlikely to be broken from the bending moment caused by the foregoing bending, the second conductor line leads 13b are not broken even when the first conductor line leads 13a are broken.

That is to say, when a line is bent in a direction orthogonal to the first conductor line leads 13a, the first conductor line leads 13a are likely to be broken; however the second conductor line leads 13b lying parallel to the bent line are not broken. Accordingly, the electrical connection between the conductor lands 12 and the corresponding conductor lines 13 can be maintained with the aid of the corresponding second conductor line leads 13b.

Referring now to FIG. 2, an FPC board according to a second embodiment of the present invention will be described. Like parts are identified by the same reference numerals as in FIG. 1 and the detailed description thereof will be omitted.

On the surface of the FPC board 10, the end electrodes of the small-size component 11 are placed, and a pair of conductor line leads 13d extending from the pair of conductor lands 12 which are electrically connected to the end electrodes by soldering are formed so as to extend across any two of four rounded corners A of the cover layer opening 14a. The conductor line leads 13d are connected to the corresponding conductor lines 13.

In other words, the small size component 11, the conductor lands 12 to which the small size component 11 is connected by soldering, and parts of the conductor line leads 13d extending from the conductor lands 12 and extending across the two of the four rounded corners A of the cover layer opening 14a are exposed to the outside from the cover layer opening 14a.

The cover layer 14 covers the ends of the conductor line leads 13d and the conductor lines 13 connected to the conductor line leads 13d.

When a bending moment is applied on the FPC board 10 having the above described structure, bending stresses in the conductor line leads 13d caused by the above bending moment are lessened by disposing the conductor line leads 13d so as to extend across the two of the four rounded corners A; as a result, the conductor line leads 13d are unlikely to be broken.

That is, when a bending moment is applied on the small size component 11 in a direction parallel to the long side or the short side of the small size component 11, since the conductor line leads 13d are not parallel to the bent line, i.e., the conductor line leads 13d have a slanted angle with respect to the bent line, the conductor line leads 13d are unlikely to be broken.

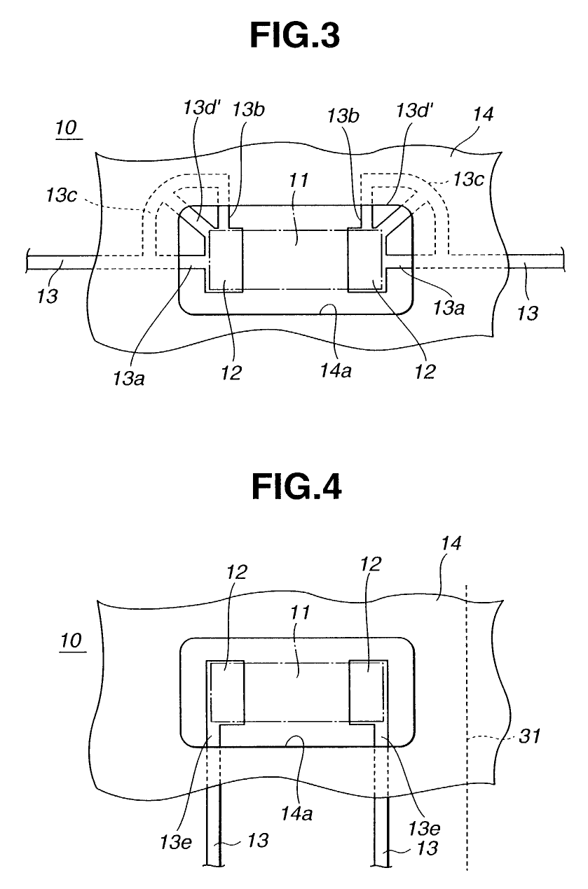

Referring now to FIG. 3, an FPC board according to a third embodiment of the present invention will be described. Like parts are identified by the same reference numerals as in FIGS. 1 and 2 and the detailed description thereof will be omitted.

The FPC board according to the third embodiment is a combination of those according to the first embodiment illustrated in FIG. 1 and the second embodiment illustrated in FIG. 2. On the surface of the FPC board 10, the first conductor line leads 13a extending from the conductor lands 12 in the longitudinal direction of the small size component 11 which is to be placed on the surface of the FPC board 10, the second conductor line leads 13b extending from the conductor lands 12 in a direction orthogonal to the first conductor line leads 13a, and a pair of third conductor line leads 13d′ extending from the conductor lands 12 and across the corners of the cover layer opening 14a between the first conductor line leads 13a and the second conductor line leads 13b are formed. The ends of the first conductor line leads 13a are connected to the corresponding conductor lines 13. Also, the ends of the second conductor line leads 13b and those of the third conductor line leads 13d′ are connected to the corresponding conductor lines 13 via the corresponding semi-circular conductor lines 13c.

Even when a bending moment is applied on the FPC board 10 having the above described structure in any direction, at least one pair of the first, second, and third conductor line leads 13a, 13b, and 13d′ are unlikely to be broken; thus the electrical connection between the small size component 11 and the conductor lines 13 can be maintained.

That is, by disposing the plurality of the first, second, and third conductor line leads 13a, 13b, and 13d′ such that at least one pair of conductor line leads among them is not parallel to the bent line in any state, at least one pair of conductor leads are unlikely to be broken from the applied bending moment.

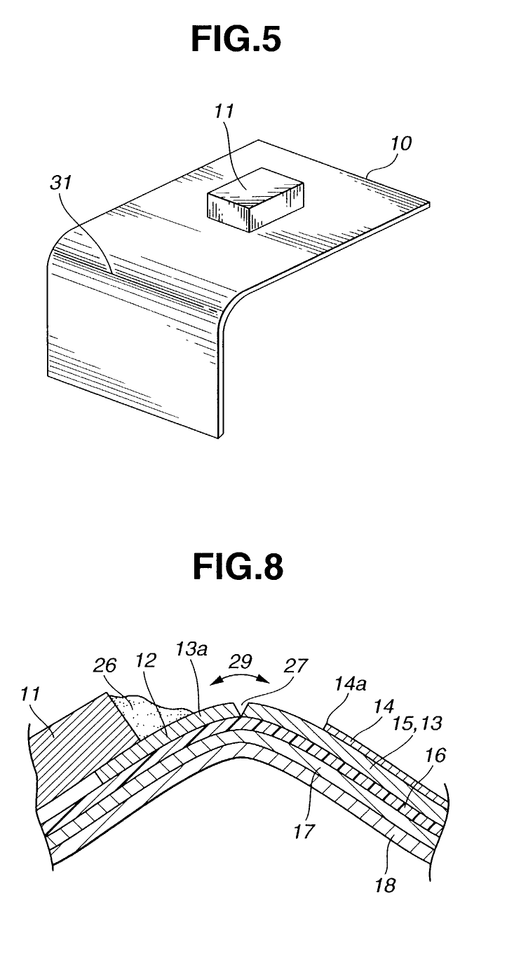

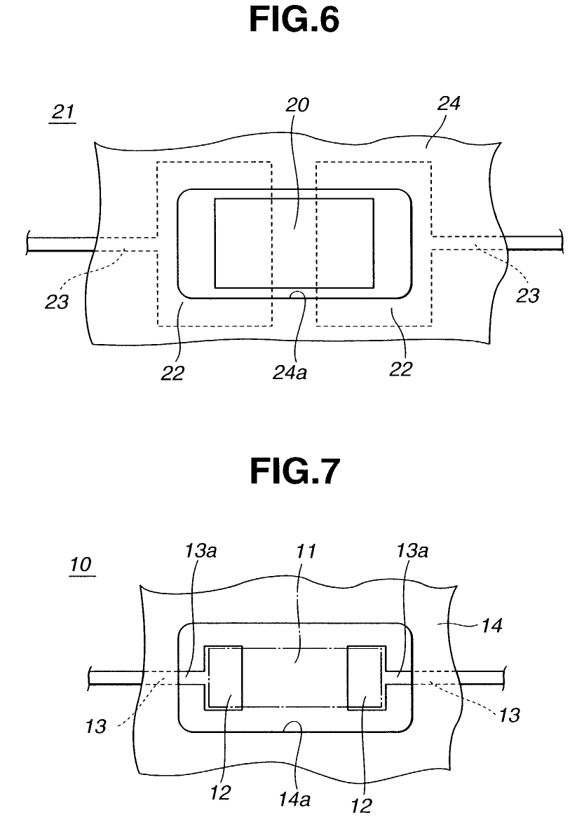

Referring now to FIGS. 4 and 5, an FPC board according to a fourth embodiment of the present invention will be described. Like parts are identified by the same reference numerals as in FIG. 1 and the detailed description thereof will be omitted.

FIG. 5 illustrates the bent state of the FPC board 10 having the small size component 11 mounted thereon, assuming that the FPC board 10 is bent along a bent line 31 lying parallel to the short side of the small size component 11.

When the small size component 11 is mounted on the FPC board 10 which is to be bent in the above described manner, the pair of conductor lands 12 to which the end electrodes of the small size component 11 are connected by soldering and a pair of conductor line leads 13e extending from the conductor lands 12 are formed on the surface of the FPC board 10 so as to be parallel to the bent line 31, as shown in FIG. 4.

With this structure, even when the FPC board 10 is bent along the bent line 31, the bending moment caused by this bending is not effectively exerted on the conductor line leads 13d; as a result, the conductor line leads 13e are unlikely to be broken.

As described above, even when a bending moment is applied on the FPC board according to any one of the above-described embodiments of the present invention, by disposing a single pair of or plural pairs of conductor line leads along a direction in which the conductor line leads are unlikely to be affected by the bending moment, the conductor line leads are unlikely to be broken. Also, even when one of the plural pairs of conductor line leads is broken, the remaining conductor line leads collectively maintain the electrical connection between a small size component and conductor lines.

In this invention, it is apparent that working modes different in a wide range can be formed on the basis of the present invention without departing from the spirit and scope of the invention. This invention is not restricted by any specific embodiment except being limited by the appended claims.

What is claimed is:

1. A flexible printed circuit board comprising:
a conductor land formed of a conductive pattern for mounting a component thereon which is to be mounted on the flexible printed circuit board;
a first conductor line lead formed of another conductive pattern which extends from the conductor land and which forms an electrical connection of the conductor land; and
a second conductor line lead formed of another conductive pattern for electrically connecting the conductor land with the first conductor line lead,
wherein the conductor land, a part of the first conductor line lead, and the second conductor line lead form a conductive loop on the flexible printed circuit board.

2. The flexible printed circuit board according to claim 1, wherein the conductor land is formed of a pair of land patterns.

3. The flexible printed circuit board according to claim 1, further comprising: a cover layer; wherein the junction between the first and second conductor line leads is sandwiched by the cover layer and a substrate of the flexible printed circuit board.

4. The flexible printed circuit board according to claim 1, further comprising: a cover layer; and a bent part, wherein the flexible printed circuit board includes an opening of the cover layer in the vicinity of the bent part, the first conductor line lead is disposed so as to be orthogonal to the bent line of the bent part, and the second conductor line lead is led out from the conductor land so as to be parallel to the bent line.

5. The flexible printed circuit board according to claim 1, further comprising: a cover layer; and a bent part, wherein the flexible printed circuit includes an opening of the cover layer in the vicinity of the bent part, the first conductor line lead is disposed so as to be orthogonal to the bent line of the bent part, and the second conductor line lead is led out from the conductor land so as not to be parallel to the bent line and to the first conductor line lead.

6. The flexible printed circuit board according to claim 1, further comprising a cover layer disposed on the surface thereof, wherein the cover layer includes an opening, and wherein the whole conductor land and parts of the first and second conductor line leads, each part lying in the vicinity of the corresponding junction with the conductor land are exposed to the outside from the opening.

7. The flexible printed circuit board according to claim 6, further comprising a bent part, wherein the cover layer includes the opening in the vicinity of the bent part, the first conductor line lead is disposed so as to be orthogonal to the bent line of the bent part, and the second conductor line lead is led out from the conductor land so as to be parallel to the bent line.

8. The flexible printed circuit board according to claim 6, further comprising a bent part, wherein the cover layer includes the opening in the vicinity of the bent part, the first conductor line lead is disposed so as to be orthogonal to the bent line of the bent part, and the second conductor line lead is led out from the conductor land so as not to be parallel to the bent line and to the first conductor line lead.

9. A flexible printed circuit board comprising:
a bent part;
a conductor land lying in the vicinity of the bent part and formed of a conductive pattern for mounting a component thereon which is to be mounted on the flexible printed circuit board;
a plurality of conductor line leads extending from the conductor land in a plurality of directions so as to form electrical connections of the conductor land; and
a cover layer disposed on the surface of the flexible printed circuit board and including an opening,
wherein the whole conductor land and parts of the plurality of conductor line leads, each part lying in the vicinity of the corresponding junction with the conductor land, are exposed to the outside from the opening.

10. The flexible printed circuit board according to claim 9, wherein the conductor land is formed of a pair of land patterns.

11. The flexible printed circuit board according to claim 9, wherein the conductor line leads other than one of the plurality of conductor line leads is connected to the one conductor line lead from the conductor land.

12. A flexible printed circuit board comprising:
a bent part;
a conductor land lying in the vicinity of the bent part and formed of a conductive pattern for mounting a component thereon which is to be mounted on the flexible printed circuit board;
a plurality of conductor line leads extending from the conductor land in a plurality of directions so as to form electrical connections of the conductor land; and
a cover layer disposed on the surface of the flexible printed circuit board and including an opening, from which the whole conductor land and parts of the plurality of conductor line leads connected to the conductor land are exposed to the outside.

13. The flexible printed circuit board according to claim 12, wherein the conductor land is formed of a pair of land patterns.

14. The flexible printed circuit board according to claim 12, wherein the conductor line leads other than one of the plurality of conductor line leads is connected to the one conductor line lead from the conductor land.

15. A flexible printed circuit board used while being bent comprising:
a conductor land lying in the vicinity of the bent part and formed of a conductive pattern for mounting a component thereon which is to be mounted on the flexible printed circuit board;
a plurality of conductor line leads extending from the conductor land in a plurality of directions so as to form electrical connections of the conductor land; and
a cover layer disposed on the surface of the flexible printed circuit board and including an opening, from which the whole conductor land and parts of the plurality of conductor line leads connected to the conductor land are exposed to the outside.

16. The flexible printed circuit board according to claim 15, wherein the conductor land is formed of a pair of land patterns.
